(19) United States
(12) Patent Application Publication
(10) Pub. No.: US 2019/0131156 A1
(43) Pub. Date: May 2, 2019

(54) SUBSTRATE TRANSFER APPARATUS AND SUBSTRATE INSPECTION APPARATUS INCLUDING THE SAME

(71) Applicant: SAMSUNG ELECTRONICS CO., LTD., Suwon-si (KR)

(72) Inventors: Won-Guk SEO, Gunpo-si (KR); Kui-Hyun YOON, Yongin-si (KR); Young HEO, Osan-si (KR)

(73) Assignee: SAMSUNG ELECTRONICS CO., LTD., Suwon-si (KR)

(21) Appl. No.: 16/102,195

(22) Filed: Aug. 13, 2018

(30) Foreign Application Priority Data
Oct. 31, 2017 (KR) 10-2017-0143630

(51) Int. Cl. H01L 21/677; G01N 21/95; H01L 21/66; H01L 21/67; H01L 21/683

(52) U.S. Cl. CPC H01L 21/67748; G01N 21/9501; H01L 21/6838; H01L 21/67288; H01L 21/67259; H01L 22/12

(57) ABSTRACT

A substrate transfer apparatus includes at least one levitation plate extending in a first direction, a first suction mover configured to be moved in the first direction along a side of the at least one levitation plate, and including a first suction pad configured to selectively suction a first part of a lower surface of a substrate, and a first rotation driving portion configured to rotate the first suction pad about a first central axis, and a second suction mover disposed to be spaced apart from the first suction mover, and configured to be moved in the first direction along the side of the at least one levitation plate, and including a second suction pad configured to selectively suction a second part of the lower surface of the substrate, and a second rotation driving portion configured to rotate the second suction pad about a second central axis.

### CROSS-REFERENCE TO RELATED APPLICATION

This application claims priority from Korean Patent Application No. 10-2017-0143630, filed on Oct. 31, 2017, in the Korean Intellectual Property Office, the contents of which are incorporated herein by reference in its entirety.

### BACKGROUND

### 1. Field

Apparatuses and methods consistent with example embodiments relate to a substrate transfer apparatus and a substrate inspection apparatus including the same, and more particularly to a substrate transfer apparatus for transferring a glass substrate such as a large area display panel in an in-line inspection apparatus and a substrate inspection apparatus including the same.

### 2. Description of the Related Art

Generally, in an in-line inspection apparatus for inspecting a glass substrate such as a display panel, a substrate transfer apparatus may be used for transferring the substrate. The substrate transfer apparatus may include a levitation plate for levitating the substrate, and a vacuum suction gripper for vacuum-suctioning and moving the substrate.

However, because a large number of driving cylinders may be required for X-axis alignment and Y-axis alignment of the substrate, costs and time to perform an inspection process may be increased greatly, and friction with the substrate may cause particles or damages to the substrate. Further, because a rotation driving range of the gripper for an angle alignment of the substrate between the levitation plates is quite limited, a process failure due to misalignment of the substrate may occur.

### SUMMARY

One or more example embodiments provide a substrate transfer apparatus capable of reducing costs and time required to perform an inspection process and precisely aligning the substrate.

One or more example embodiments also provide a substrate inspection apparatus including the same.

According to example embodiments, a substrate transfer apparatus includes at least one levitation plate extending in a first direction and having spray holes through which a gas is injected to levitate a substrate, and a first suction mover configured to be moved in the first direction along a side of the at least one levitation plate. The first suction mover includes a first suction pad configured to selectively suction a first part of a lower surface of the substrate, and a first rotation driving portion configured to rotate the first suction pad about a first central axis. The substrate transfer apparatus further includes a second suction mover spaced apart from the first suction mover, and configured to be moved in the first direction along the side of the at least one levitation plate. The second suction mover includes a second suction pad configured to selectively suction a second part of the lower surface of the substrate, and a second rotation driving portion configured to rotate the second suction pad about a second central axis.

According to example embodiments, a substrate transfer apparatus includes a first levitation plate extending in a first direction, a second levitation plate extending in the first direction, and disposed opposite to the first levitation plate in a second direction perpendicular to the first direction, each of the first levitation plate and the second levitation plate having spray holes through which a gas is injected to levitate a substrate. The substrate transfer apparatus further includes a guide rail extending in the first direction, and disposed between the first levitation plate and the second levitation plate, and a first suction mover configured to be moved along the guide rail, the first suction mover including a first suction pad configured to selectively suction a first part of a lower surface of the substrate, and a first rotation driving portion configured to rotate the first suction pad about a first central axis. The substrate transfer apparatus further includes a second suction mover disposed to be spaced apart from the first suction mover in the first direction, and configured to be moved along the guide rail, the second suction mover including a second suction pad configured to selectively suction a second part of the lower surface of the substrate, and a second rotation driving portion configured to rotate the second suction pad about a second central axis.

According to example embodiments, a substrate inspection apparatus includes a first levitation plate extending in a first direction, a second levitation plate extending in the first direction, and disposed opposite to the first levitation plate in a second direction perpendicular to the first direction, each of the first levitation plate and the second levitation plate having spray holes through which a gas is injected to levitate a substrate. The substrate inspection apparatus further includes a guide rail extending in the first direction, and disposed between the first levitation plate and the second levitation plate, and a first suction mover configured to be moved along the guide rail, the first suction mover including a first suction pad configured to selectively suction a first part of a lower surface of the substrate, and a first rotation driving portion configured to rotate the first suction pad about a first central axis. The substrate inspection apparatus further includes a second suction mover disposed to be spaced apart from the first suction mover in the first direction, and configured to be moved along the guide rail, the second suction mover including a second suction pad configured to selectively suction a second part of the lower surface of the substrate, and a second rotation driving portion configured to rotate the second suction pad about a second central axis. he substrate inspection apparatus further includes an inspection module configured to detect a defect in the substrate that is transferred by the first suction mover and the second suction mover.

### BRIEF DESCRIPTION OF THE DRAWINGS

Example embodiments will be more clearly understood from the following detailed description taken in conjunction with the accompanying drawings, in which:

FIG. 1 is a cross-sectional view illustrating a substrate inspection apparatus in accordance with example embodiments;

FIG. 2 is a plan view illustrating a substrate transfer apparatus of the substrate inspection apparatus in FIG. 1;

FIG. 3 is a plan view illustrating a substrate transfer module of the substrate transfer apparatus in FIG. 2;

FIG. 4 is a cross-sectional view illustrating the substrate transfer module in FIG. 3;

FIG. 5 is a block diagram illustrating a controller of the substrate transfer apparatus in FIG. 2;

FIG. 6 is a flow chart illustrating a method of inspecting a substrate, using a substrate inspection apparatus, in accordance with example embodiments; and.

FIGS. 7A, 7B, 7C and 7D are plan views illustrating a substrate transfer method in accordance with example embodiments.

### DETAILED DESCRIPTION

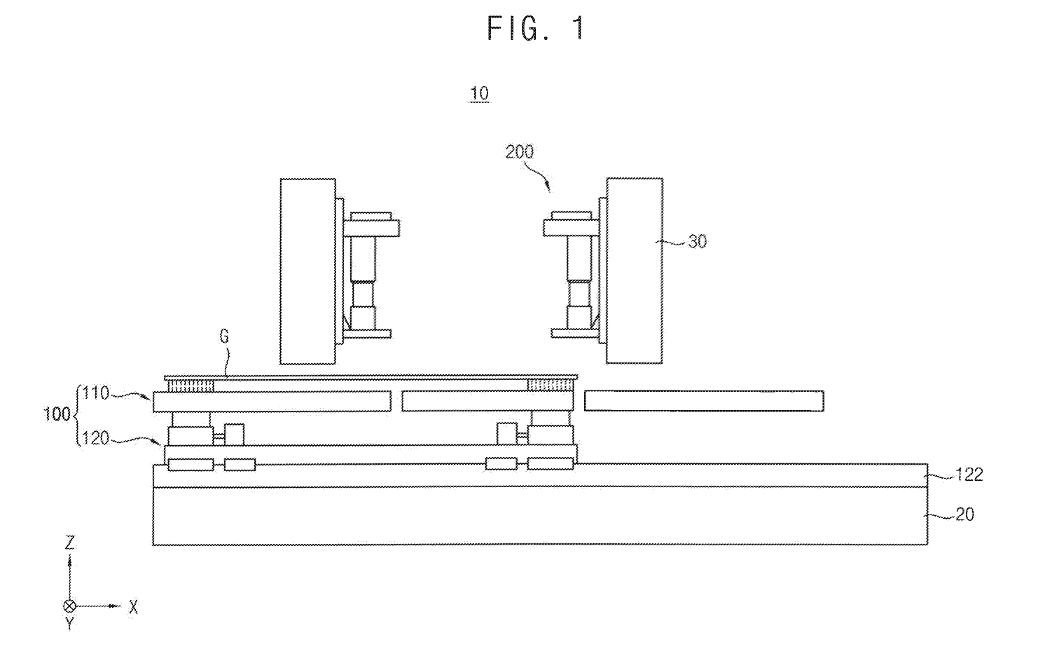

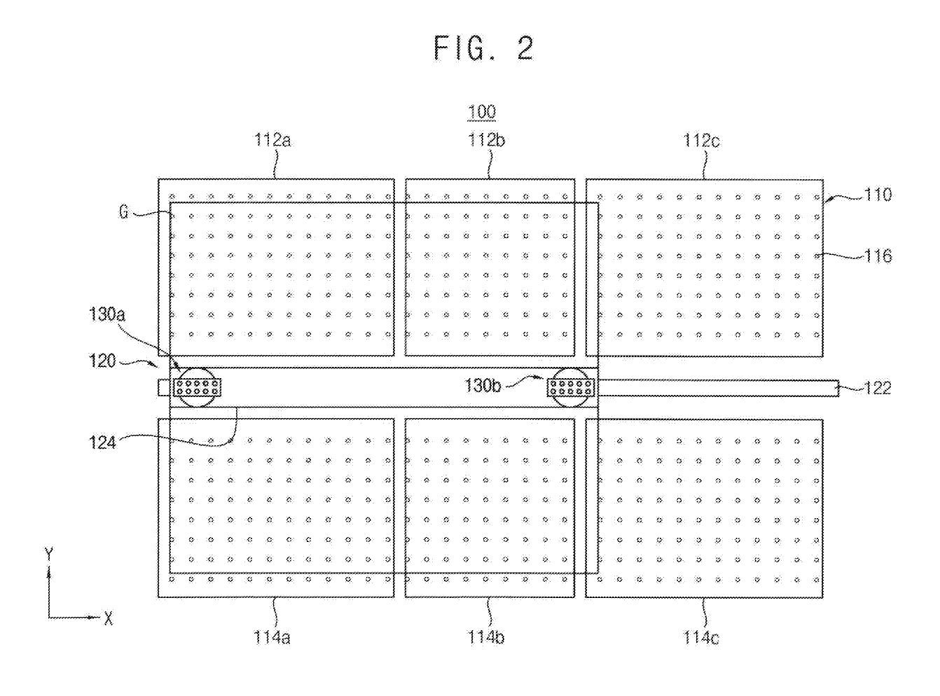

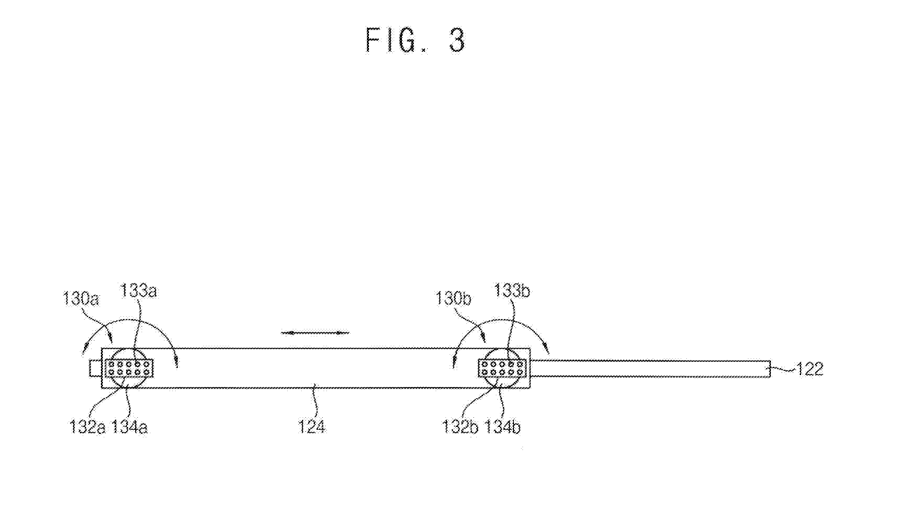

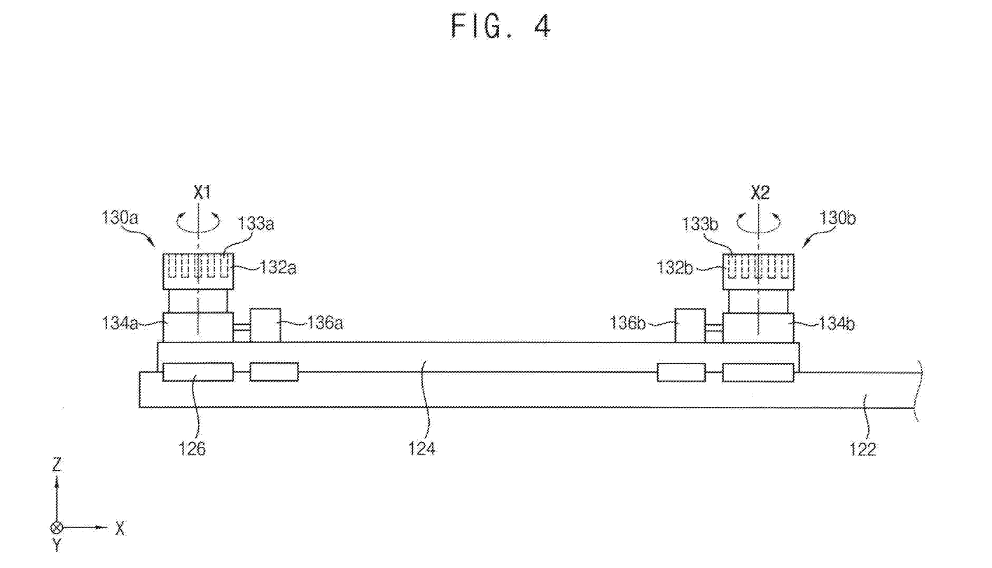

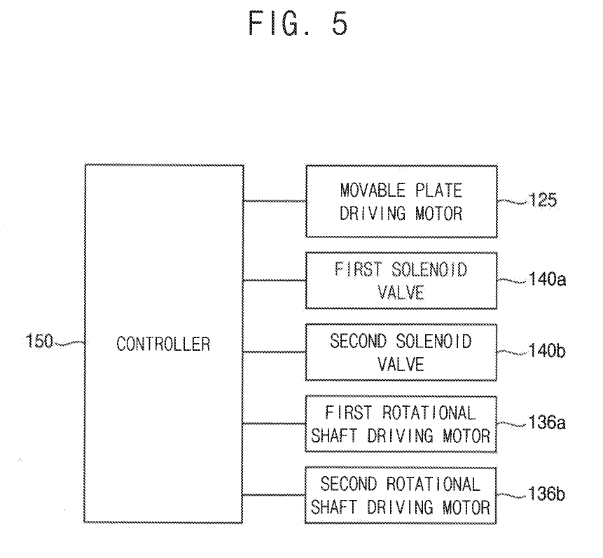

FIG. 1 is a cross-sectional view illustrating a substrate inspection apparatus in accordance with example embodiments. FIG. 2 is a plan view illustrating a substrate transfer apparatus of the substrate inspection apparatus in FIG. 1. FIG. 3 is a plan view illustrating a substrate transfer module of the substrate transfer apparatus in FIG. 2. FIG. 4 is a cross-sectional view illustrating the substrate transfer module in FIG. 3. FIG. 5 is a block diagram illustrating a controller of the substrate transfer apparatus in FIG. 2.

Referring to FIGS. 1 to 5, a substrate inspection apparatus 10 may include a substrate transfer apparatus 100 configured to align and transfer a loaded substrate G, and an inspection module 200 configured to detect a defect in the substrate G transferred by the substrate transfer apparatus 100.

In example embodiments, the substrate inspection apparatus 10 may be an in-line inspection apparatus that obtains an image of the substrate G to detect a defect while transferring the substrate G such as TFT LCD panel or OLED panel. For example, the substrate inspection apparatus 10 may include a scan section, a review section and an unloading section. The substrate transfer apparatus 100 may align and transfer the loaded substrate G in the scan section, and the inspection module 200 may detect a defect in the transferred substrate G in the review section.

As illustrated in FIG. 1, the substrate transfer apparatus 100 may be installed in a support frame 20, and a plurality of the inspection modules 200 may be installed in a bridge 30 that is supported on the support frame 20 and extends in one direction. Accordingly, the inspection module 200 may be disposed over the substrate transfer apparatus 100. The inspection module 200 may include an optic lens, CCD camera, an illumination light source, etc. The inspection module 200 may capture an image of the substrate G transferred by the substrate transfer apparatus 100 and detect various defects using vision image processing algorism.

The substrate transfer apparatus 100 may include a substrate levitation module 110 to inject a gas toward a lower surface of the substrate G to levitate the substrate G, and a substrate transfer module 120 to align and transfer the substrate G levitated by the substrate levitation module 110.

The substrate levitation module 110 may include at least one levitation plate that extends in a first direction (X-direction) and has a plurality of spray holes 116 for injecting the gas to levitate the substrate G.

The substrate levitation module 110 may include a pair of first and second levitation plates that are arranged to be opposite to each other and extend parallel with each other. The first levitation plate may include a plurality of first plates 112a, 112b, 112c that extend in the first direction (X-direction) respectively. The second levitation plate may include a plurality of second plates 114a, 114b, 114c that extend in the first direction (X-direction) corresponding to the first plates respectively. The corresponding first and second plates may be arranged to be spaced apart from each other in a second direction (Y-direction) perpendicular to the first direction.

The levitation plate may have a rectangular shape. The levitation plate may have a plurality of the spray holes 116 in an upper surface thereof, through which the gas is injected toward the lower surface of the substrate G.

The substrate transfer module 120 may be arranged between the first and second levitation plates. The substrate transfer module 120 may include a first suction mover 130a and a second suction mover 130b that are movable in the first direction (X-direction) and are installed to be spaced apart from each other. A distance between the first suction mover 130a and the second suction mover 130b may be determined in consideration of a length of the substrate G in the first direction (X-direction).

The substrate transfer module 120 may include a guide rail 122 extending in the first direction between the first and second levitation plates and a movable plate 124 installed to be movable along the guide rail 122 and on which the first and second suction movers 130a, 130b are installed to be spaced apart from each other. The movable plate 124 may be installed in the guide rail 122 by movable blocks 126. The substrate transfer module 120 may include a ball screw combined with the movable block 126 and a movable plate driving motor 125 rotating the ball screw to move the movable plate 124. The driving portion for moving the movable plate 124 may not be limited thereto, and it may be understood that various modifications are possible.

Accordingly, as the movable plate 124 moves along the guide rail 122, the first suction mover 130a and the second suction mover 130b installed fixedly on the movable plate 124 respectively may move in the first direction (X-direction) along the guide rail 122.

Alternatively, the movable plate may be omitted, and the first and second suction movers 130a, 130b may be installed directly in the guide rail 122 by movable blocks. In this case, the substrate transfer module 120 may include a ball screw combined with the movable blocks and a driving motor to rotate the ball screw to move the first and second suction movers 130a, 130b.

As illustrated in FIGS. 3 and 4, the first suction mover 130a may include a first suction pad 132a to selectively suction a portion (a first part) of the lower surface of the substrate G, and a first rotation driving portion 134a to operatively rotate the first suction pad 132a about a first central axis X1. The second suction mover 130b may include a second suction pad 132b to selectively suction a portion (a second part) of the lower surface of the substrate G, and a second rotation driving portion 134b to operatively rotate the second suction pad 132b about a second central axis X2.

A plurality of first vacuum holes 133a may be formed in an upper surface of the first suction pad 132a, and a plurality of second vacuum holes 133b may be formed in an upper surface of the second suction pad 132b. The first vacuum hole 133a may be connected to a first vacuum line having a first solenoid valve 140a installed therein, and the second vacuum hole 133b may be connected to a second vacuum line having a second solenoid valve 140b installed therein. When the first solenoid valve 140a operates (ON), a vacuum pressure may be formed in the first vacuum hole 133a, and thus, the first suction pad 132a may suction the substrate G. When the second solenoid valve 140b operates (ON), a vacuum pressure may be formed in the second vacuum hole 133b, and thus, the second suction pad 132b may suction the substrate G.

The first rotation driving portion 134a may have a first rotational shaft connected to the first suction pad 132a and rotating the first suction pad 132a about the first central axis X1. The second rotation driving portion 134b may have a second rotational shaft connected to the second suction pad 132b and rotating the second suction pad 132b about the second central axis X2.

The first suction mover 130a may include a first rotational shaft driving motor 136a for driving the first rotational shaft of the first rotation driving portion 134a, and the second suction mover 130b may include a second rotational shaft driving motor 136b for driving the second rotational shaft of the second rotation driving portion 134b.

As the first rotational shaft of the first rotation driving portion 134a is rotated by a predetermined angle by the first rotational shaft driving motor 136a, the first suction pad 132a may rotate about the first central axis X1 by the predetermined angle. As the second rotational shaft of the second rotation driving portion 134b is rotated by a predetermined angle by the second rotational shaft driving motor 136b, the second suction pad 132b may rotate about the second central axis X2 by the predetermined angle.

As illustrated in FIG. 5, the controller may control the substrate transfer module 120 to align and transfer the loaded substrate G.

The movable plate driving motor 125 may be operatively connected to a controller 150. The movable plate driving motor 125 may be driven by a control signal of the controller 150 to move the movable plate 124 such that the first and second suction movers 130a, 130b move along the guide rail 122 in the first direction (X-direction).

The first and second solenoid valves 140a, 140b may be operatively connected to the controller 150. When the first solenoid valve 140a operates (ON) by a control signal, a vacuum pressure may be formed in the first vacuum hole 133a, and thus, the first suction pad 132a may suction the substrate G. When the second solenoid valve 140b operates (ON) by a control signal, a vacuum pressure may be formed in the second vacuum hole 133b, and thus, the second suction pad 132b may suction the substrate G.

The first and second rotational shaft driving motors 136a, 136b may be operatively connected to the controller 150. The first rotational shaft driving motor 136a may be driven by a control signal to rotate the first rotational shaft of the first rotation driving portion 134a by a predetermined angle such that the first suction pad 132a rotates about the first central axis X1 by the predetermined angle. The second rotational shaft driving motor 136b may be driven by a control signal to rotate the second rotational shaft of the second rotation driving portion 134b by a predetermined angle such that the second suction pad 132b rotates about the second central axis X2 by the predetermined angle.

In example embodiments, the substrate transfer module 120 of the substrate transfer apparatus 100 may align and transfer the substrate G levitated by the substrate levitation module 110. The first and second suction movers 130a, 130b of the substrate transfer module 120 may align a position in the second direction (Y-direction) of the substrate G (Y-axis alignment), and then, may transfer the substrate G in the first direction (X-direction).

The substrate transfer module 120 may perform either one or both of a first rotation operation in which, in a first state that the first suction pad 132a suctions the substrate G and the second suction pad 132b does not suction the substrate G, the first rotation driving portion 134a rotates such that the suctioned substrate G is rotated about the first central axis X1, and a second rotation operation in which, in a second state that the first suction pad 132a does not suction the substrate G and the second suction pad 132b suctions the substrate G, the second rotation driving portion 134b rotates such that the suctioned substrate G is rotated about the second central axis X2, to align the position in the second direction (Y-direction) of the substrate G.

The substrate transfer module 120 may transfer the substrate G along the guide rail 122 in the first direction (X-direction) in a third state that the first and second suction pads 132a, 132b suction the substrate G.

Accordingly, by a selective combination of the rotation operation and the suction operation of the first and second suction pads 132a, 132b of the first and second suction movers 130a, 130b, the Y-axis alignment of the substrate G may be performed, and then the X-axis transfer of the substrate G may be performed.

Hereinafter, a method of inspecting a substrate using the substrate inspection apparatus in FIG. 1 will be explained.

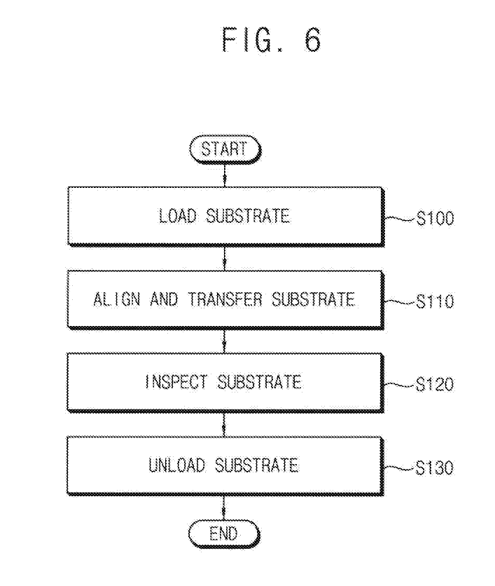

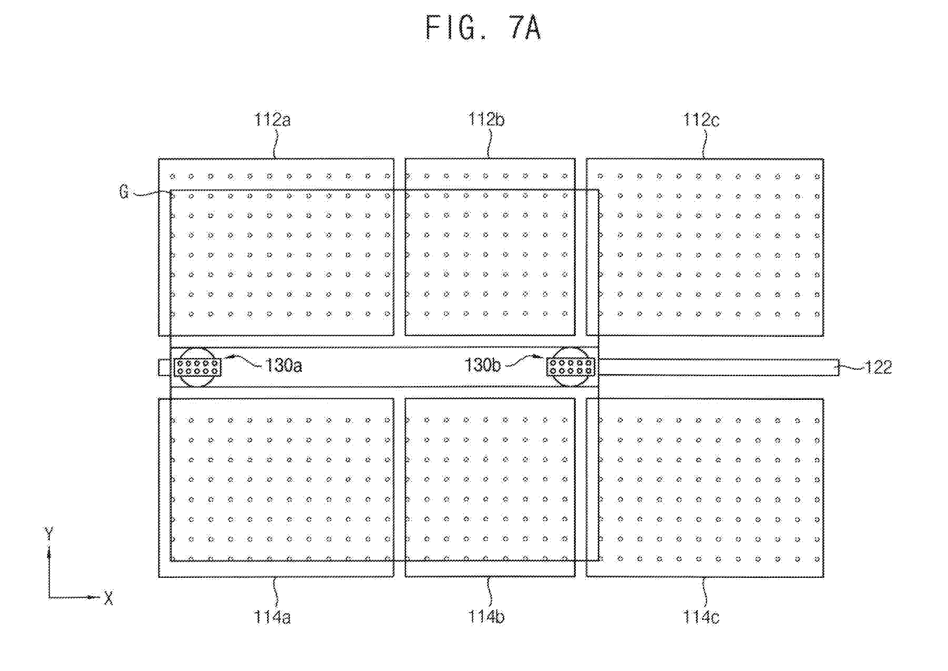

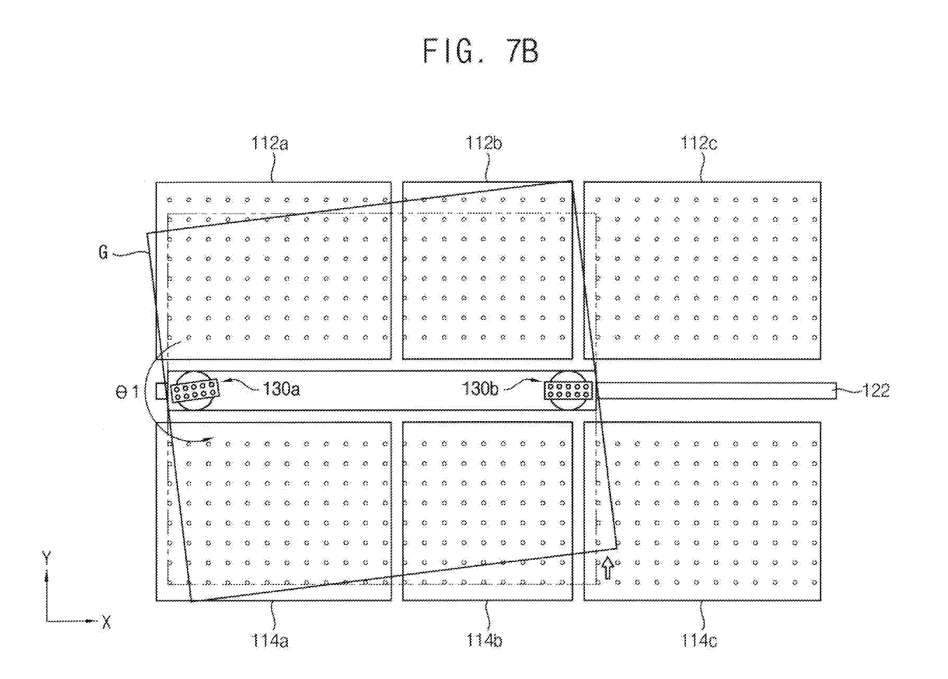

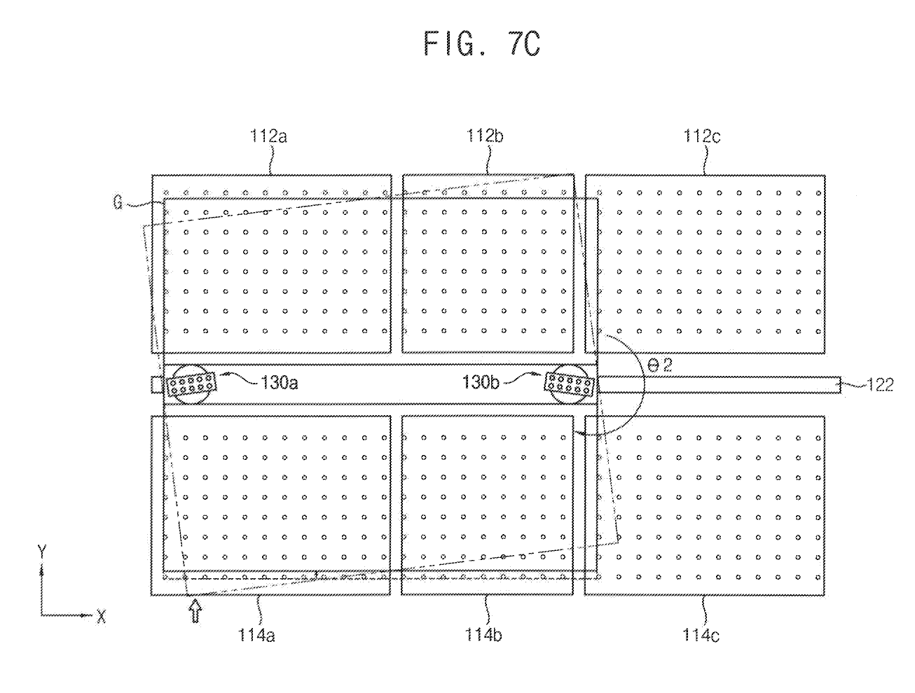

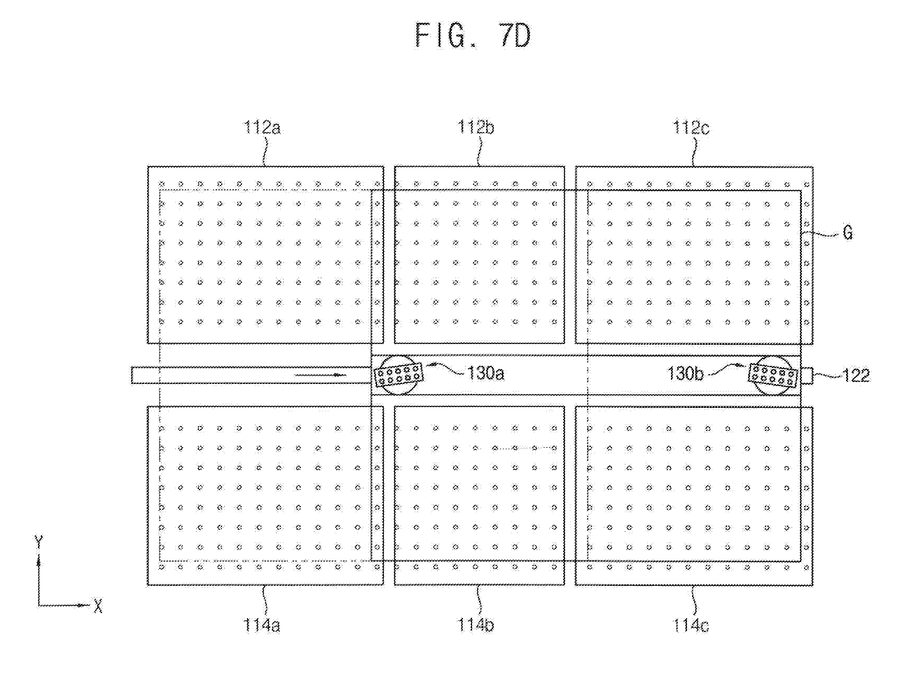

FIG. 6 is a flow chart illustrating a method of inspecting a substrate, using a substrate inspection apparatus, in accordance with example embodiments. FIGS. 7A, 7B, 7C and 7D are plan views illustrating a substrate transfer method in accordance with example embodiments.

Referring to FIGS. 1, 2, 6, 7A and 7B, first, the substrate G may be loaded into the substrate inspection apparatus 10 (S100), and then, the substrate G may aligned and transferred in the substrate inspection apparatus 10 (S110).

First, the substrate G may be loaded onto first and second levitation plates in a scan section. The first levitation plate may include the plurality of first plates 112, 112b, 112c that extend in the first direction (X-direction) respectively. The second levitation plate may include the plurality of second plates 114a, 114b, 114c that extend in the first direction (X-direction) corresponding to the first plates respectively.

Then, the first and second suction movers 130a, 130b of the substrate transfer module 120 may align a position in a second direction (Y-direction) of the substrate G (Y-axis alignment), and then, may transfer the substrate G in the first direction (X-direction).

As illustrated in FIG. 7A, an original position of the substrate G that is loaded onto the first and second levitation plates may be misaligned in the second direction (Y-direction)

As illustrated in FIG. 7B, a first rotation operation in which, in a state that the first suction pad 132a suctions the substrate G and the second suction pad 132b does not suction the substrate G, the first rotation driving portion 134a rotates such that the suctioned substrate G is rotated about the first central axis X1 by a predetermined angle θ1, may be performed.

As illustrated in FIG. 7C, a second rotation operation in which, in a state that the first suction pad 132a does not suction the substrate G and the second suction pad 132b suctions the substrate G, the second rotation driving portion 134b rotates such that the suctioned substrate G is rotated about the second central axis X2 by a predetermined angle θ2, to align the position in the second direction (Y-direction) of the substrate G, may be performed.

As illustrated in FIG. 7D, in a state that the first and second suction pads 132a, 132b suction the substrate G, the movable plate 124 may be moved along the guide rail 122 to move the substrate G in the first direction (X-direction)

Then, the transferred substrate G may be inspected (S120), and then, the substrate G may be unloaded (S130).

The inspection module 200 may capture an image of the substrate G and detect various defects, using a vision image processing algorism.

The substrate transfer apparatus 100 may transfer the inspected substrate G from a revive section to an unloading section. In the unloading section, the substrate G may be unloaded.

As mentioned above, the substrate transfer apparatus 100 may include at least two suction movers movable in X-direction and spaced apart from each other. Each of the suction movers may include a suction pad to selectively suction a portion of a lower surface of the substrate G, and a rotation driving portion to operatively rotate the suction pad about a respective central axis. By a selective combination of a rotation operation and a suction operation of each of the suction pads of the at least two suction movers, the Y-axis alignment of the substrate G may be performed and then the X-axis transfer of the substrate G may be performed.

Accordingly, costs and time to perform an inspection process may be reduced, and the substrate may be aligned precisely to thereby improve inspection accuracy.

The substrate inspection apparatus in accordance with example embodiments may be used to inspect defects in patterns formed on a substrate in manufacturing processes of a display device such as a liquid crystal display device, a plasma display device, etc.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the inventive concept. Accordingly, all such modifications are intended to be included within the scope of example embodiments as defined in the claims.

What is claimed is:

1. A substrate transfer apparatus comprising:
at least one levitation plate extending in a first direction and having spray holes through which a gas is injected to levitate a substrate;
a first suction mover configured to be moved in the first direction along a side of the at least one levitation plate, the first suction mover comprising:
a first suction pad configured to selectively suction a first part of a lower surface of the substrate; and
a first rotation driving portion configured to rotate the first suction pad about a first central axis; and
a second suction mover spaced apart from the first suction mover, and configured to be moved in the first direction along the side of the at least one levitation plate, the second suction mover comprising:
a second suction pad configured to selectively suction a second part of the lower surface of the substrate; and
a second rotation driving portion configured to rotate the second suction pad about a second central axis.

2. The substrate transfer apparatus of claim 1, further comprising:
a guide rail extending in the first direction; and
a movable plate configured to be moved in the first direction along the guide rail,
wherein the first suction mover and the second suction mover are disposed in the movable plate, and
wherein the first suction mover is spaced apart from the second suction mover in the first direction.

3. The substrate transfer apparatus of claim 2, further comprising movable blocks,
wherein the movable plate is disposed in the guide rail by the movable blocks.

4. The substrate transfer apparatus of claim 3, wherein the first suction mover and the second suction mover are disposed fixedly on the movable plate.

5. The substrate transfer apparatus of claim 1, wherein the first suction mover comprises a first rotational shaft driving motor configured to drive a first rotational shaft of the first rotation driving portion, and
wherein the second suction mover comprises a second rotational shaft driving motor configured to drive a second rotational shaft of the second rotation driving portion.

6. The substrate transfer apparatus of claim 1, wherein the first rotation driving portion is further configured to, in a first state in which the first suction pad suctions the substrate and the second suction pad does not suction the substrate, rotate the first suction pad such that the substrate is rotated about the first central axis, to align the substrate in a second direction perpendicular to the first direction, and
wherein the second rotation driving portion is further configured to, in a second state in which the first suction pad does not suction the substrate and the second suction pad suctions the substrate, rotate the second suction pad such that the substrate is rotated about the second central axis, to align the substrate in the second direction.

7. The substrate transfer apparatus of claim 6, wherein the first suction mover and the second suction mover are further configured to, in a third state in which the first suction pad and the second suction pad suction the substrate and the substrate is aligned in the second direction, be moved in the first direction.

8. The substrate transfer apparatus of claim 1, wherein the at least one levitation plate comprises a first levitation plate and a second levitation plate disposed opposite to the first levitation plate in a second direction perpendicular to the first direction, and
wherein the first suction mover and the second suction mover are disposed between the first levitation plate and the second levitation plate.

9. The substrate transfer apparatus of claim 8, further comprising a guide rail extending in the first direction, and disposed between the first levitation plate and the second levitation plate,
wherein the first suction mover and the second suction mover are disposed in the guide rail.

10. The substrate transfer apparatus of claim 1, wherein a first upper surface of the first suction pad and a second upper surface of the second suction pad are disposed higher than a third upper surface of the at least one levitation plate.

11. A substrate transfer apparatus, comprising:
a first levitation plate extending in a first direction;
a second levitation plate extending in the first direction, and disposed opposite to the first levitation plate in a second direction perpendicular to the first direction, each of the first levitation plate and the second levitation plate having spray holes through which a gas is injected to levitate a substrate;
a guide rail extending in the first direction, and disposed between the first levitation plate and the second levitation plate;
a first suction mover configured to be moved along the guide rail, the first suction mover comprising:
a first suction pad configured to selectively suction a first part of a lower surface of the substrate; and
a first rotation driving portion configured to rotate the first suction pad about a first central axis; and
a second suction mover spaced apart from the first suction mover in the first direction, and configured to be moved along the guide rail, the second suction mover comprising:
a second suction pad configured to selectively suction a second part of the lower surface of the substrate; and
a second rotation driving portion configured to rotate the second suction pad about a second central axis.

12. The substrate transfer apparatus of claim 11, further comprising a movable plate configured to be moved in the first direction along the guide rail,
wherein the first suction mover and the second suction mover are disposed in the movable plate.

13. The substrate transfer apparatus of claim 11, wherein the first suction mover comprises a first rotational shaft driving motor configured to drive a first rotational shaft of the first rotation driving portion, and
wherein the second suction mover comprises a second rotational shaft driving motor configured to drive a second rotational shaft of the second rotation driving portion.

14. The substrate transfer apparatus of claim 11, wherein the first rotation driving portion is further configured to, in a first state in which the first suction pad suctions the substrate and the second suction pad does not suction the substrate, rotate the first suction pad such that the substrate is rotated about the first central axis, to align the substrate in the second direction, and
wherein the second rotation driving portion is further configured to, in a second state in which the first suction pad does not suction the substrate and the second suction pad suctions the substrate, rotate the second suction pad such that the substrate is rotated about the second central axis, to align the substrate in the second direction.

15. The substrate transfer apparatus of claim 14, wherein the first suction mover and the second suction mover are further configured to, in a third state in which the first suction pad and the second suction pad suction the substrate and the substrate is aligned in the second direction, be moved in the first direction.

16. A substrate inspection apparatus comprising:
a first levitation plate extending in a first direction;
a second levitation plate extending in the first direction, and disposed opposite to the first levitation plate in a second direction perpendicular to the first direction, each of the first levitation plate and the second levitation plate having spray holes through which a gas is injected to levitate a substrate;
a guide rail extending in the first direction, and disposed between the first levitation plate and the second levitation plate;
a first suction mover configured to be moved along the guide rail, the first suction mover comprising:
a first suction pad configured to selectively suction a first part of a lower surface of the substrate; and
a first rotation driving portion configured to rotate the first suction pad about a first central axis;
a second suction mover disposed to be spaced apart from the first suction mover in the first direction, and configured to be moved along the guide rail, the second suction mover comprising:
a second suction pad configured to selectively suction a second part of the lower surface of the substrate; and
a second rotation driving portion configured to rotate the second suction pad about a second central axis; and
an inspection module configured to detect a defect in the substrate that is transferred by the first suction mover and the second suction mover.

17. The substrate inspection apparatus of claim 16, further comprising a movable plate configured to be moved in the first direction along the guide rail,
wherein the first suction mover and the second suction mover are disposed in the movable plate.

18. The substrate inspection apparatus of claim 16, wherein first upper surfaces of the first suction pad and the second suction pad are positioned higher than second upper surfaces of the first levitation plate and the second levitation plate.

19. The substrate inspection apparatus of claim 16, wherein the first rotation driving portion is further configured to, in a first state in which the first suction pad suctions the substrate and the second suction pad does not suction the substrate, rotate the first suction pad such that the substrate is rotated about the first central axis, to align the substrate in the second direction, and
wherein the second rotation driving portion is further configured to, in a second state in which the first suction pad does not suction the substrate and the second suction pad suctions the substrate, rotate the second suction pad such that the substrate is rotated about the second central axis, to align the substrate in the second direction.

20. The substrate inspection apparatus of claim 19, wherein the first suction mover and the second suction mover are further configured to, in a third state in which the first suction pad and the second suction pad suction the substrate and the substrate is aligned in the second direction, be moved in the first direction.
